(19) United States
(12) Patent Application Publication
(10) Pub. No.: US 2014/0365838 A1
(43) Pub. Date: Dec. 11, 2014

(54) INTEGRATED CIRCUIT COMPRISING TEST CIRCUITRY FOR TESTING FAN-OUT PATHS OF A TEST CONTROL PRIMARY INPUT

(71) Applicant: LSI Corporation, San Jose, CA (US)

(72) Inventors: Ramesh C. Tekumalla, Breinigsville, PA (US); Vijay Sharma, Pune (IN)

(21) Appl. No.: 13/914,753

(22) Filed: Jun. 11, 2013

(51) Int. Cl. G01R 31/3177

(52) U.S. Cl. CPC G01R 31/3177
USPC 714/726

(57) ABSTRACT

An integrated circuit comprises a primary input adapted to receive a test control signal, a primary output, and logic circuits having inputs coupled to the primary input via respective fan-out paths of the primary input. The integrated circuit further includes first test circuitry configured for testing a designated portion of the integrated circuit in a first test mode of operation with the test control signal at a first logic value, and second test circuitry coupled between the inputs of the logic circuits and the primary output and configured for testing of the fan-out paths in a second test mode of operation in which the test control signal takes on both the first logic value and a second logic value associated with a functional mode of operation. The primary input, primary output, logic circuits and test circuitry may be associated with a particular circuit core of the integrated circuit.

### FIELD

The field relates generally to integrated circuits, and more particularly to testing of integrated circuits.

### BACKGROUND

Integrated circuits typically incorporate some form of test circuitry. For example, integrated circuits may be designed to incorporate scan test circuitry that facilitates testing for various internal fault conditions. Such scan test circuitry typically comprises scan chains comprising multiple scan cells. The scan cells may be implemented, by way of example, utilizing respective flip-flops. The scan cells of a given scan chain are configurable to form a serial shift register for applying test patterns at inputs to combinational logic of the integrated circuit. The scan cells of the given scan chain are also used to capture outputs from other combinational logic of the integrated circuit.

Scan testing of an integrated circuit may therefore be viewed as being performed in two repeating phases, namely, a scan shift phase in which the flip-flops of the scan chain are configured as a serial shift register for shifting in and shifting out of test patterns, and a scan capture phase in which the flip-flops of the scan chain capture combinational logic outputs. These two repeating scan test phases may be collectively referred to herein as a scan test mode of operation of the integrated circuit, or as simply a scan mode of operation. Outside of the scan test mode and its scan shift and scan capture phases, the integrated circuit may be said to be in a functional mode of operation. Other definitions of the scan test and functional operating modes may also be used.

An integrated circuit may also be configured to include built-in self-test (BIST) capabilities. Such BIST capabilities in some implementations make use of scan test circuitry and operating modes of the type described above. BIST implementations may be configured to test particular portions of an integrated circuit, such as a memory. BIST testing of integrated circuit memories is also referred to as memory BIST (MBIST). MBIST is typically used to detect faults that are internal to the memory.

However, conventional scan test circuitry and MBIST arrangements are often unable to detect certain faults associated with fan-out paths of a primary input that receives a test control signal having a single logic value during testing. Undetected faults associated with these fan-out paths can cause the integrated circuit to fail in the field.

### SUMMARY

In one embodiment, an integrated circuit comprises a primary input adapted to receive a test control signal, a primary output, and a plurality of logic circuits having inputs coupled to the primary input via respective fan-out paths of the primary input. The integrated circuit further includes first test circuitry configured for testing a designated portion of the integrated circuit in a first test mode of operation with the test control signal at a first logic value, and second test circuitry coupled between the inputs of the logic circuits and the primary output and configured for testing of the fan-out paths in a second test mode of operation in which the test control signal takes on both the first logic value and a second logic value associated with a functional mode of operation.

By way of example only, the primary input, primary output, logic circuits and test circuitry may be associated with a particular circuit core of the integrated circuit, such as a system-on-chip (SOC) circuit core.

Other embodiments of the invention include but are not limited to methods, apparatus, systems, processing devices and computer-readable storage media having computer program code embodied therein.

### BRIEF DESCRIPTION OF THE DRAWINGS

FIG. 1 is a block diagram of a testing system comprising a tester and an integrated circuit having test control logic with associated test circuitry for testing fan-out paths of a test control primary input in one embodiment.

FIGS. 2 and 4 show exemplary embodiments of the test circuitry associated with the test control logic of the integrated circuit of FIG. 1.

FIGS. 3 and 5 provide timing diagrams that illustrate the operation of the test circuitry of FIGS. 2 and 4, respectively.

FIG. 6 is a block diagram of a processing system for generating an integrated circuit design comprising test circuitry of the type illustrated in FIGS. 1, 2 and 4.

FIG. 7 is a block diagram of an exemplary processing device that incorporates the integrated circuit of FIG. 1.

### DETAILED DESCRIPTION

Embodiments of the invention will be illustrated herein in conjunction with exemplary integrated circuits comprising test circuitry for supporting testing of other internal circuitry of those integrated circuits. It should be understood, however, that embodiments of the invention are more generally applicable to any integrated circuit in which it is desirable to provide improved testing of fan-out paths of a primary input that receives a test control signal.

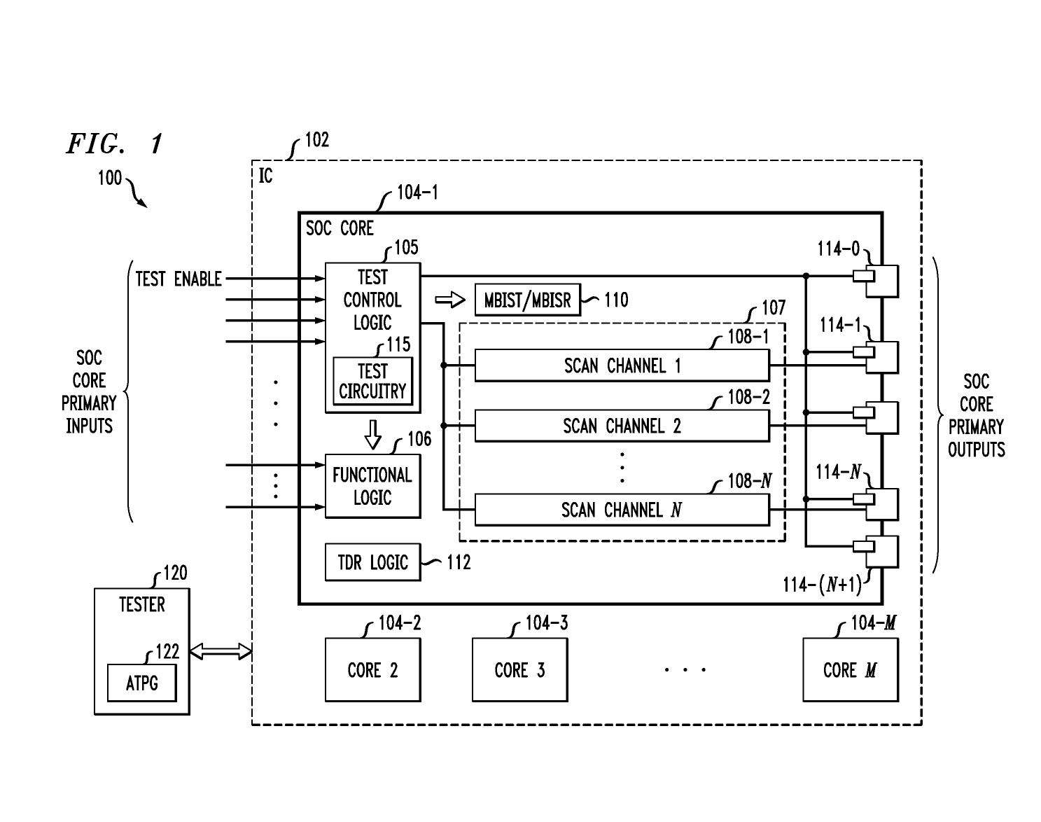

FIG. 1 shows an embodiment of the invention in which a testing system 100 comprises an integrated circuit under test 102. The integrated circuit 102 in this embodiment comprises a plurality of circuit cores 104 including a system-on-chip (SOC) core 104-1 and a number of additional circuit cores 104-2, 104-3, . . . 104-M. One or more of the additional circuit cores 104-2 through 104-M may comprise, for example, respective embedded memories, or sets of processing circuitry of various types. In other embodiments, the integrated circuit 102 may comprise only a single circuit core.

The SOC core 104-1 may comprise, for example, a read channel core configured for use in a hard disk drive (HDD) controller application, designed for reading and writing data from one or more magnetic storage disks of an HDD. Numerous other types of SOC cores may be used in other embodiments.

The integrated circuit 102 further comprises test control logic 105, functional logic 106 and scan circuitry 107. The test control logic 105 and functional logic 106 are driven by primary inputs of the SOC core 104-1. The test control logic 105 may comprise, for example, decoder logic utilized to control testing of the SOC core 104-1 and possibly other portions of the integrated circuit 102. The scan circuitry 107 comprises a plurality of scan channels 108-1, 108-2, . . . 108-N that are driven by the test control logic 105 and are associated with respective primary outputs of the SOC core 104-1. The scan channels 108 are assumed to comprise scan chains each comprising multiple scan cells.

Also associated with the integrated circuit 102 in this embodiment are MBIST circuitry 110, test data register (TDR) logic 112 and output buffers 114. The test control logic 105 interacts with the MBIST circuitry 110 and will also typically interact with the TDR logic 112 although the latter interaction is not explicitly illustrated in the figure. In other embodiments, one or both of the MBIST circuitry 110 and TDR logic 112 may be wholly or partially incorporated into the test control logic 105. The MBIST circuitry 110 may comprise, for example, a controller coupled to an embedded memory for performing conventional MBIST testing of the embedded memory using techniques that are known to those skilled in the art. Also incorporated in or otherwise associated with the MBIST circuitry 110 may be memory built-in self-recovery (MBISR) functionality.

The output buffers 114 include output buffers 114-0, 114-1, 114-2, . . . 114-N and 114-(N+1), each of which is controlled by an output of the test control logic 105. The output buffers 114-1 through 114-N also have inputs coupled to respective outputs of the scan channels 108-1 through 108-N.

The test control logic 105 of the SOC core 104-1 further comprises test circuitry 115. This test circuitry is in addition to the test circuitry comprising scan test circuitry 107 and MBIST circuitry 110. As will be described in more detail below, the test circuitry 115 provides an ability to test fan-out paths of a given primary input that receives a test control signal.

The integrated circuit 102 is coupled to a tester 120 that comprises an automatic test pattern generator (ATPG) 122. The ATPG may be viewed as an example of what is more generally referred to herein as a test generation tool.

Among other functions, the tester 120 stores scan data associated with scan testing of the integrated circuit 102. Such scan data comprises input test patterns provided by the ATPG 122 for shifting into the scan channels 108 as well as corresponding output scan data shifted out of the scan channels 108 and resulting from application of the input test patterns to the integrated circuit 102. In other embodiments, at least a portion of the tester 120, such as the ATPG 122, may be incorporated into the integrated circuit 102. Alternatively, the entire tester 120 may be incorporated into the integrated circuit 102, in an embodiment that implements scan testing as part of a BIST arrangement.

Embodiments of the present invention may be configured to utilize compressed or noncompressed scan testing implemented via the exemplary scan test circuitry 107 comprising scan channels 108. Accordingly, scan test circuitry 107 in one or more embodiments may further comprise a decompressor for decompressing compressed scan patterns to be applied to the scan channels 108, and a compressor for compressing outputs received from the scan channels 108.

At least a portion of the primary inputs and the primary outputs of the SOC core 104-1 are assumed to be connected to the tester 120 during testing of the integrated circuit 102, although such connections between the tester and the primary inputs and outputs are not explicitly shown in the figure. Also, the integrated circuit 102 will typically also include additional primary inputs and primary outputs, possibly associated with other circuitry of the SOC core 104-1 or the additional circuit cores 104-2 through 104-M. Only a limited number of exemplary primary inputs and primary outputs are shown in the figure for simplicity and clarity of illustration.

In the present embodiment, a given one of the primary inputs associated with test control logic 105 is adapted to receive a test control signal denoted TEST ENABLE. This test control signal may be supplied to the primary input by the tester 120. Other types of test control signals in any combination may be used in other embodiments. The term “test control signal” as used herein is therefore intended to be broadly construed and should be understood to encompass, for example, a single-bit signal, a multi-bit signal, and other types of logic signals not necessarily based on binary logic.

It is assumed that the TEST ENABLE signal has a single logic value during testing of the SOC core 104-1 of the integrated circuit 102. For example, this single logic value may be either a logic 0 value or a logic 1 value in the case of a single-bit binary TEST ENABLE signal. In such an arrangement, during testing the TEST ENABLE signal may be set to the logic 1 value, and during functional operation of the integrated circuit 102 the TEST ENABLE signal may be set to the logic 0 value. Thus, during testing the TEST ENABLE signal is maintained at a fixed logic value.

As mentioned previously, such an arrangement does not permit conventional scan test circuitry or MBIST circuitry to detect certain faults associated with fan-out paths of the corresponding primary input. The given primary input that receives the TEST ENABLE signal in this embodiment is assumed to have multiple such fan-out paths. Accordingly, the SOC core 104-1 is assumed to comprise multiple logic circuits that have inputs coupled to the given primary input via respective fan-out paths of that primary input. Portions of these logic circuits may be within the test control logic 105 and additionally or alternatively within other portions of the integrated circuit, such as the functional logic 106. Thus, the given primary input that receives the TEST ENABLE signal is assumed to fan out to multiple distinct portions of the integrated circuit 102.

It was indicated above that the test control logic 105 in the present embodiment is configured to include additional test circuitry 115 that provides an ability to test the above-noted fan-out paths of the TEST ENABLE primary input. This allows faults associated with these fan-out paths to be detected and thereby reduces the number of failures in the field. The test circuitry 115 is an example of what is more generally referred to herein as “second test circuitry” of the integrated circuitry 102. Such second test circuitry is in addition to other test circuitry of the integrated circuit 102, which in the present embodiment illustratively includes scan circuitry 107 and MBIST circuitry 110. These latter components may be viewed individually or collectively as one or more examples of what is more generally referred to herein as “first test circuitry” of the integrated circuit 102.

The first test circuitry referred to above is generally configured for testing a designated portion of the integrated circuit 102 in a first test mode of operation with the test control signal TEST ENABLE maintained at a first logic value, such as the logic 1 value. The second test circuitry is coupled between inputs of logic circuits that receive the TEST ENABLE signal via respective fan-out paths and one of the primary outputs. The second test circuitry is configured for testing of the fan-out paths in a second test mode of operation in which the TEST ENABLE signal takes on both the first logic value and a second logic value associated with a functional mode of operation.

For example, in the second test mode of operation, the TEST ENABLE signal may be varied between the logic 1 value typically associated with the first test mode of operation and the logic 0 value typically associated with the functional mode of operation. As will be described in greater detail below, this allows the detection of certain types of faults on the fan-out paths of the TEST ENABLE primary input that would not otherwise be detectable using the scan circuitry 107 or MBIST circuitry 110.

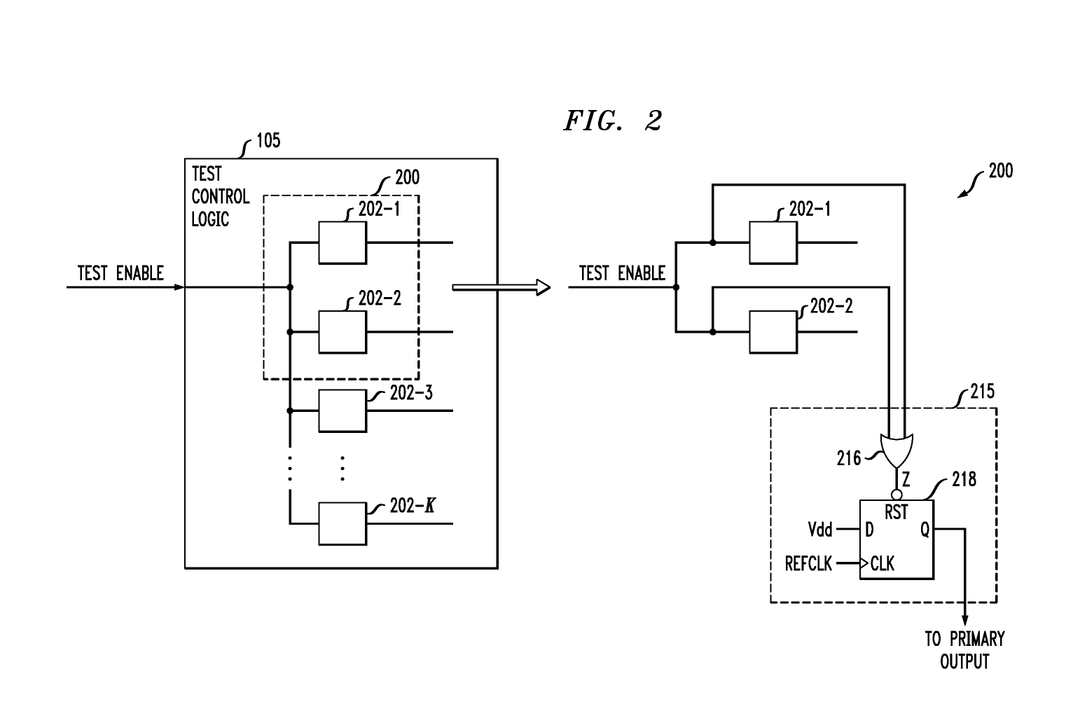

The second test mode may therefore comprise at least first and second phases in which the test control signal is at the respective first and second logic values, with the test circuitry 115 being illustratively configured to permit detection of a stuck-at fault on at least one of the fan-out paths through observation of the primary output in the first and second phases. The stuck-at fault is detected if a logic value observed at the primary output is different than its expected logic value given the logic value of the TEST ENABLE signal in the corresponding phase of the second test mode. Exemplary arrangements of this type will be described in greater detail below in conjunction with FIGS. 2 through 5.

It is to be appreciated that the particular configuration of testing system 100 comprising integrated circuit 102 and tester 120 as shown in FIG. 1 is exemplary only, and the testing system 100 in other embodiments may include other elements in addition to or in place of those specifically shown, including one or more elements of a type commonly found in a conventional implementation of such a system. For example, various elements of the integrated circuit 102, tester 120 or other parts of the system 100 may be implemented, by way of illustration only and without limitation, utilizing a microprocessor, central processing unit (CPU), digital signal processor (DSP), application-specific integrated circuit (ASIC), field-programmable gate array (FPGA), or other type of data processing device, as well as portions or combinations of these and other devices.

Thus, the integrated circuit 102 need not include any particular arrangement of circuit cores, primary inputs, primary outputs, logic circuits and other components. For example, as noted above, circuit cores in other embodiments may comprise respective internal memories or other sets of processing circuitry of the integrated circuit, in any combination. The term “circuit core” as used herein is therefore intended to be broadly construed. Also, terms such as “primary input” and “primary output” are also intended to be broadly construed, and generally encompass respective pin-level input and output terminals of an integrated circuit, in any of a variety of different physical configurations.

The integrated circuit 102 may be configured for installation on a circuit board or other mounting structure in a computer, server, mobile telephone or other type of communication device. Such communication devices may also be viewed as examples of what are more generally referred to herein as “processing devices.” The latter term is also intended to encompass storage devices, as well as other types of devices comprising data processing circuitry.

Referring now to FIG. 2, a portion 200 of one potential configuration of the integrated circuit 102 is shown in greater detail. As illustrated, the portion 200 is assumed to be implemented in the test control logic 105 in this embodiment and comprises first and second logic circuits 202-1 and 202-2 having respective inputs coupled to the TEST ENABLE primary input via respective fan-out paths of that primary input. Test circuitry 215 of the portion 200 of test control logic 105 is coupled between the inputs of the logic circuits and a primary output and is configured for testing of the fan-out paths the above-noted second test mode of operation in which the test control signal takes on both the first logic value and a second logic value associated with a functional mode of operation.

The test circuitry 215 in this embodiment comprises a logic gate 216 having inputs coupled to respective ones of the inputs of the logic circuits 202-1 and 202-2, and a flip-flop 218 having an active low reset input coupled to an output of the logic gate 216. The logic gate 216 is illustratively implemented as an OR gate, but other arrangements of one or more logic gates may be used. The flip-flop 218 has a data input (D) coupled to an upper voltage potential Vdd, a data output (Q) coupled to the primary output, and a clock input (CLK) adapted to receive a free-running reference clock signal denoted REFCLK.

In operation, one or more portions of the integrated circuit 102 are tested in the above-noted first test mode of operation with the TEST ENABLE signal applied to the primary input at a first logic value, illustratively a logic 1 value. Also, the fan-out paths between the TEST ENABLE primary input and the inputs of respective logic circuits 202-1 and 202-2 are tested in the above-noted second test mode of operation in which the TEST ENABLE signal takes on both the first logic value, illustratively a logic 1 value, and a second logic value associated with a functional mode of operation. The second logic value is illustratively a logic 0 value. Again, alternative arrangements of logic values, test control signals and test modes of operations may be used in other embodiments.

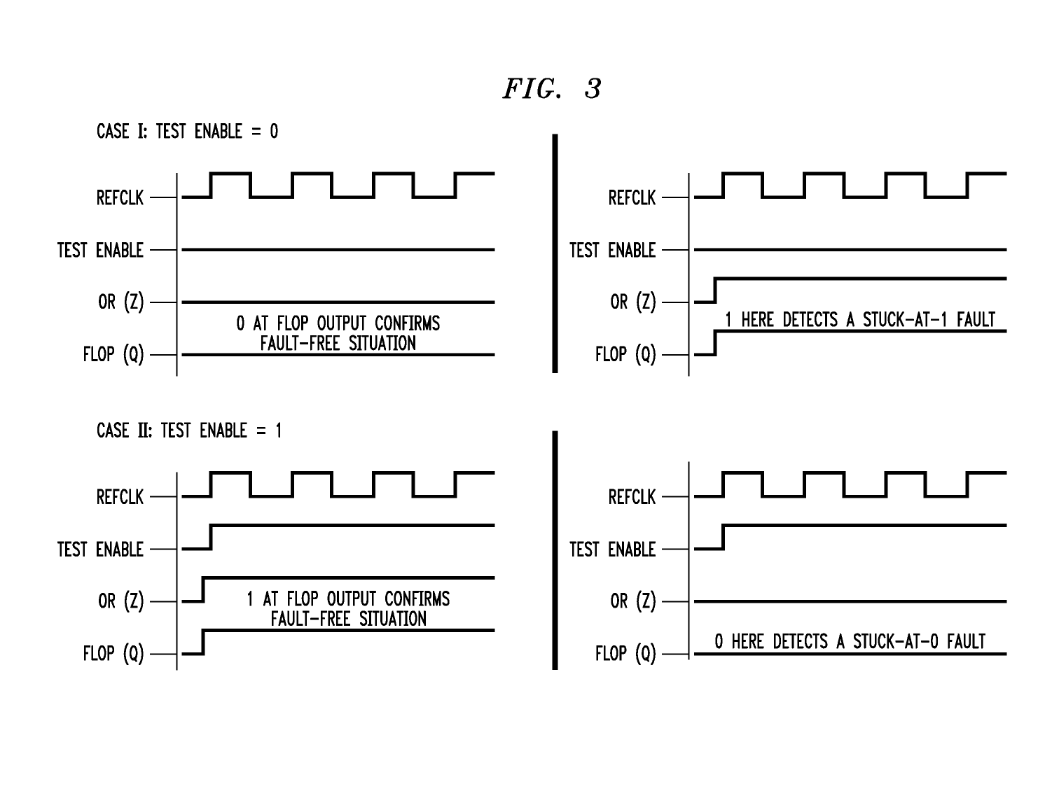

The second test mode of operation is illustrated in the timing diagrams of FIG. 3, which show the free-running reference clock REFCLK, the test control signal TEST ENABLE, the OR gate output (Z) and the flip-flop data output (Q) for both fault-free and stuck-at fault conditions in each of the cases TEST ENABLE=0 and TEST ENABLE=1. These cases are denoted as Case I and Case II, respectively, in the figure.

Testing of the fan-out paths in this second test mode of operation may be viewed as comprising two distinct phases corresponding to the respective TEST ENABLE=0 and TEST ENABLE=1 cases. The TEST ENABLE signal is applied at the logic 0 value in the first phase of the second test mode, and the primary output is observed. The TEST ENABLE signal is then applied at the logic 1 value in the second phase of the second test mode, and the primary output is again observed. A stuck-at fault is detected on at least one of the fan-out paths based on the observations of the primary output in the first and second phases. More particularly, a stuck-at fault is detected if the logic value observed at the primary output is different than its expected logic value given the logic value of the TEST ENABLE signal in the corresponding phase of the second test mode.

Referring now more particularly to Case I of FIG. 3, in which TEST ENABLE=0 in the first phase of the second test mode of operation, the timing diagram on the left for Case I illustrates a fault-free condition and the corresponding timing diagram on the right shows a detected stuck-at-1 fault condition on one of the fan-out paths of the TEST ENABLE primary input.

A logic 1 value at the Q output of the flip-flop 218 in Case I identifies a stuck-at-1 fault on one of the fan-out paths of the TEST ENABLE primary input. This is because setting TEST ENABLE=0 would be expected to result in a logic 0 value at the output of the OR gate 216, and therefore a logic 0 value at the Q output of the flip-flop 218, under the fault-free condition illustrated in the timing diagram on the left. The stuck-at-1 fault is identified in Case I when the primary output is at a logic 1 value instead of the expected logic 0 value, as illustrated in the timing diagram on the right.

With reference now to Case II of FIG. 3, in which TEST ENABLE=1 in the second phase of the second test mode of operation, the timing diagram on the left for Case II illustrates a fault-free condition and the corresponding timing diagram on the right shows a detected stuck-at-0 fault condition on one of the fan-out paths of the TEST ENABLE primary input.

A logic 0 value at the Q output of the flip-flop 218 in Case II identifies a stuck-at-0 fault on one of the fan-out paths of the TEST ENABLE primary input. This is because setting TEST ENABLE=1 would be expected to result in a logic 1 value at the output of the OR gate 216, and therefore a logic 1 value at the Q output of the flip-flop 218, under the fault-free condition illustrated in the timing diagram on the left. The stuck-at-0 fault is identified in Case II when the primary output is at a logic 0 value instead of the expected logic 1 value, as illustrated in the timing diagram on the right.

It is therefore apparent that both stuck-at-1 and stuck-at-0 faults on the fan-out paths of the TEST ENABLE primary input are detectable using the test circuitry 215 in conjunction with appropriate setting of the TEST ENABLE logic value in the first and second phases of the second test mode of operation. Such faults are generally not detectable using conventional test circuitry such as scan test circuitry 107 and MBIST circuitry 110. This is because the faults are associated with fan-out paths of a test control primary input that is maintained at a single logic value during testing.

It should be noted that the arrangement shown in FIG. 2 is simplified for clarity of illustration. In other embodiments, additional logic circuits 202-3 through 202-K of the test control logic 105 may similarly have their inputs coupled to respective additional inputs of the OR gate 216, or alternative arrangements of one or more logic gates may be used to accommodate testing of the TEST ENABLE primary input fan-out paths to such additional logic circuit inputs. For example, trees of multiple logic gates may be implemented in the test circuitry 215 in order to accommodate testing of a large number of fan-out paths in a straightforward manner.

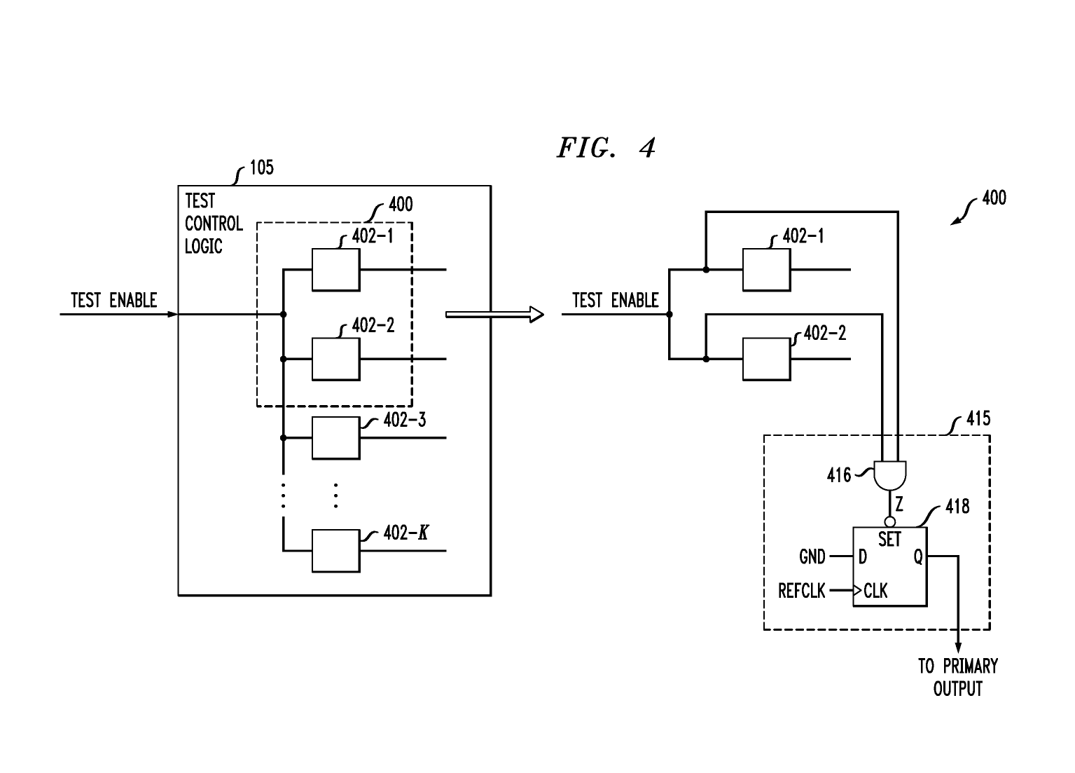

FIG. 4 shows an alternative embodiment in which a portion 400 of the integrated circuit implemented in the test control logic 105 comprises first and second logic circuits 402-1 and 402-2 having respective inputs coupled to the TEST ENABLE primary input via respective fan-out paths of that primary input. Test circuitry 415 of the portion 400 of test control logic 105 is coupled between the inputs of the logic circuits and a primary output and is configured for testing of the fan-out paths the above-noted second test mode of operation in which the test control signal takes on both the first logic value and a second logic value associated with a functional mode of operation.

The test circuitry 415 in this embodiment comprises a logic gate 416 having inputs coupled to respective ones of the inputs of the logic circuits 402-1 and 402-2, and a flip-flop 418 having an active low set input coupled to an output of the logic gate 416. The logic gate 416 is illustratively implemented as an AND gate, but as indicated previously other arrangements of one or more logic gates may be used. The flip-flop 418 has a data input (D) coupled to ground potential Gnd, a data output (Q) coupled to the primary output, and a clock input (CLK) adapted to receive a free-running reference clock signal denoted REFCLK.

In operation, one or more portions of the integrated circuit 102 are tested in the above-noted first test mode of operation with the TEST ENABLE signal applied to the primary input at a first logic value, illustratively a logic 1 value. Also, the fan-out paths between the TEST ENABLE primary input and the inputs of respective logic circuits 402-1 and 402-2 are tested in the above-noted second test mode of operation in which the TEST ENABLE signal takes on both the first logic value, illustratively a logic 1 value, and a second logic value associated with a functional mode of operation. The second logic value is illustratively a logic 0 value. Again, alternative arrangements of logic values, test control signals and test modes of operations may be used in other embodiments.

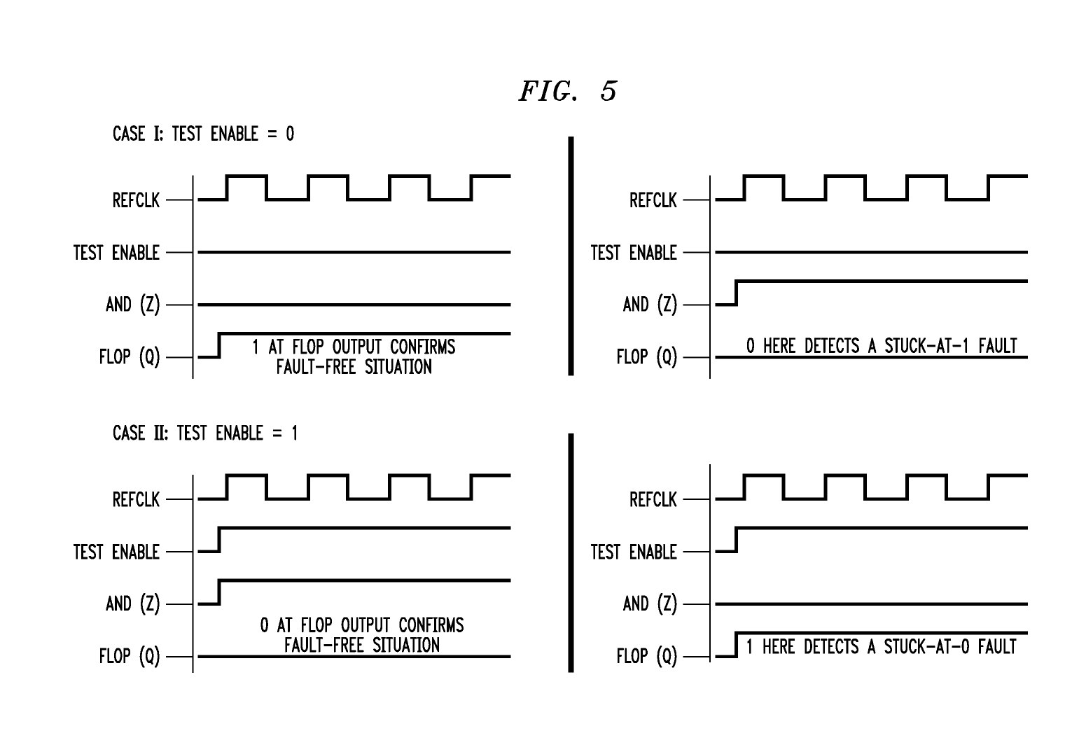

The second test mode of operation is illustrated in the timing diagrams of FIG. 5, which show the free-running reference clock REFCLK, the test control signal TEST ENABLE, the AND gate output (Z) and the flip-flop data output (Q) for both fault-free and stuck-at fault conditions in each of the cases TEST ENABLE=0 and TEST ENABLE=1. These cases are denoted as Case I and Case II, respectively, in the figure.

As in the embodiment previously described in conjunction with FIGS. 2 and 3, testing of the fan-out paths in this second test mode of operation once again may be viewed as comprising two distinct phases corresponding to the respective TEST ENABLE=0 and TEST ENABLE=1 cases. The TEST ENABLE signal is applied at the logic 0 value in the first phase of the second test mode, and the primary output is observed. The TEST ENABLE signal is then applied at the logic 1 value in the second phase of the second test mode, and the primary output is again observed. A stuck-at fault is detected on at least one of the fan-out paths based on the observations of the primary output in the first and second phases. More particularly, a stuck-at fault is detected if the logic value observed at the primary output is different than its expected logic value given the logic value of the TEST ENABLE signal in the corresponding phase of the second test mode.

Referring now more particularly to Case I of FIG. 5, in which TEST ENABLE=0 in the first phase of the second test mode of operation, the timing diagram on the left for Case I illustrates a fault-free condition and the corresponding timing diagram on the right shows a detected stuck-at-1 fault condition on one of the fan-out paths of the TEST ENABLE primary input.

A logic 0 value at the Q output of the flip-flop 418 in Case I identifies a stuck-at-1 fault on one of the fan-out paths of the TEST ENABLE primary input. This is because setting TEST ENABLE=0 would be expected to result in a logic 0 value at the output of the AND gate 416, and therefore a logic 1 value at the Q output of the flip-flop 418, under the fault-free condition illustrated in the timing diagram on the left. The stuck-at-1 fault is identified in Case I when the primary output is at a logic 0 value instead of the expected logic 1 value, as illustrated in the timing diagram on the right.

With reference now to Case II of FIG. 5, in which TEST ENABLE=1 in the second phase of the second test mode of operation, the timing diagram on the left for Case II illustrates a fault-free condition and the corresponding timing diagram on the right shows a detected stuck-at-0 fault condition on one of the fan-out paths of the TEST ENABLE primary input.

A logic 1 value at the Q output of the flip-flop 418 in Case II identifies a stuck-at-0 fault on one of the fan-out paths of the TEST ENABLE primary input. This is because setting TEST ENABLE=1 would be expected to result in a logic 1 value at the output of the AND gate 416, and therefore a logic 0 value at the Q output of the flip-flop 418, under the fault-free condition illustrated in the timing diagram on the left. The stuck-at-0 fault is identified in Case II when the primary output is at a logic 1 value instead of the expected logic 0 value, as illustrated in the timing diagram on the right.

It is therefore apparent that both stuck-at-1 and stuck-at-0 faults on the fan-out paths of the TEST ENABLE primary input are detectable using the test circuitry 415 in conjunction with appropriate setting of the TEST ENABLE logic value in the first and second phases of the second test mode of operation. Again, such faults are generally not detectable using conventional test circuitry such as scan test circuitry 107 and MBIST circuitry 110.

Like the arrangement of FIG. 2, the arrangement shown in FIG. 4 is simplified for clarity of illustration. In other embodiments, additional logic circuits 402-3 through 402-K of the test control logic 105 may similarly have their inputs coupled to respective additional inputs of the AND gate 416, or alternative arrangements of one or more logic gates may be used to accommodate testing of the TEST ENABLE primary input fan-out paths to such additional logic circuit inputs. For example, trees of multiple logic gates may be implemented in the test circuitry 415 in order to accommodate testing of a large number of fan-out paths in a straightforward manner.

It is to be appreciated that the particular test circuitry 215 and 415 described above in conjunction with respective FIGS. 2 and 4 is presented by way of example only, and other embodiments can use different arrangements of logic gates, flip-flops or other circuitry to provide the desired functionality. As one more particular example of an alternative arrangement of test circuitry, the second test circuitry in other embodiments may comprise a plurality of scan cells coupled to respective ones of the inputs of the logic circuits, with these scan cells being configured into a separate scan chain that permits testing of the fan-out paths of the TEST ENABLE primary input. The term “test circuitry” as used herein is therefore intended to be broadly construed.

Also, a wide variety of other types of test control signals, primary inputs, primary outputs, logic circuits and sets of integrated circuit operating modes and phases may be used in other embodiments. Also, numerous other arrangements of circuit cores, functional logic, scan test circuitry, MBIST circuitry and possibly additional or alternative elements, may be used to implement the described functionality.

The test circuitry arrangements described in conjunction with FIGS. 1 through 5 provide significantly improved fault coverage in the integrated circuit 102 without requiring substantial additional area overhead or timing overhead. Accordingly, the associated functionality can be implemented in one or more of the embodiments without any significant negative impact on integrated circuit area requirements or functional timing requirements.

The tester 120 in the testing system 100 of FIG. 1 need not take any particular form, and various conventional testing system arrangements can be modified in a straightforward manner to support the testing of fan-out paths of a test control primary input as disclosed herein. For example, a tester in one embodiment comprises a load board, with an integrated circuit to be subject to scan testing using the techniques disclosed herein being installed in a central portion of the load board. The tester also comprises processor and memory elements for executing stored program code. A given such processor can be used to implement at least a portion of an ATPG or other type of test pattern generator, and associated input and output test data is stored in the memory. Numerous alternative testers may be used to perform testing of an integrated circuit as disclosed herein. Also, as indicated previously, in alternative embodiments at least portions of the tester 120 of the testing system 100 may be incorporated into the integrated circuit itself, as in a BIST arrangement.

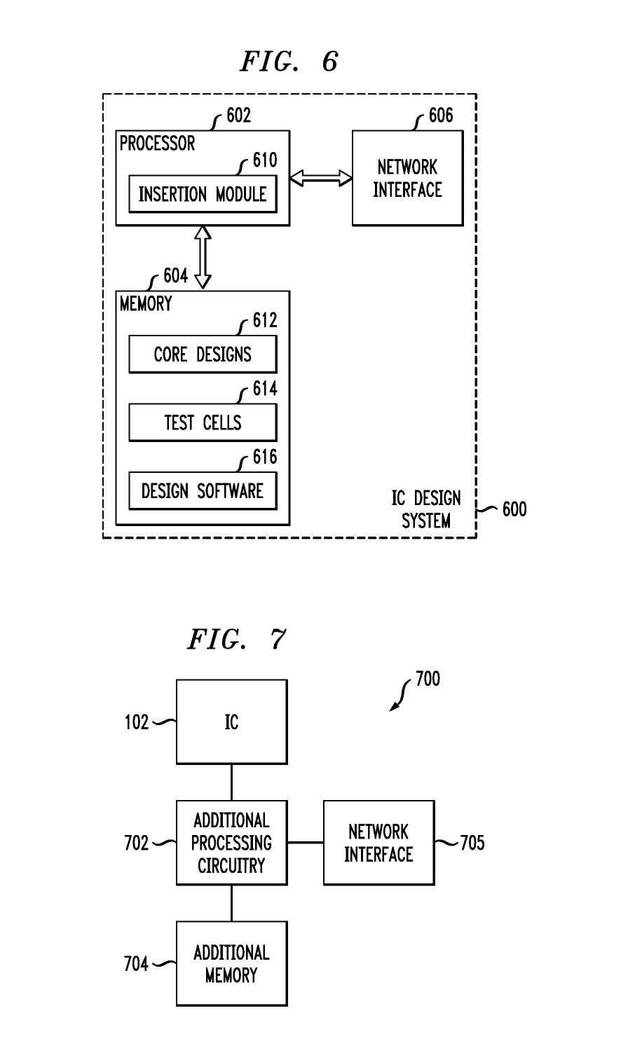

The insertion of test circuitry 215 or 415 in a given integrated circuit design may be performed in a processing system 600 of the type shown in FIG. 6. Such a processing system in this embodiment more particularly comprises a design system configured for use in designing integrated circuits such as integrated circuit 102 to include scan test circuitry 107, MBIST circuitry 110 and additional test circuitry 115 associated with test control logic 105.

The system 600 comprises a processor 602 coupled to a memory 604. Also coupled to the processor 602 is a network interface 606 for permitting the processing system to communicate with other systems and devices over one or more networks. The network interface 606 may therefore comprise one or more transceivers. The processor 602 implements a test circuitry insertion module 610 for supplementing core designs 612 with test cells 614 and other associated circuit elements in the manner disclosed herein, in conjunction with utilization of integrated circuit design software 616.

By way of example, fan-out paths may be extracted from one or more core designs for each of a plurality of test control primary inputs. Additional paths are established from respective points as close as possible to respective inputs of logic circuits driven by the respective fan-out paths. These additional paths are coupled to inputs of one or more inserted logic gates such as OR gate 216 or AND gate 416, which as previously noted may be combined with other gates into a tree structure in order to accommodate testing of a large number of test control primary input fan-out paths. Flip-flops such as flip-flop 218 or flip-flop 418 are then inserted, and their respective outputs coupled to respective primary outputs of the integrated circuit.

Elements such as 610, 612, 614 and 616 are implemented at least in part in the form of software stored in memory 604 and processed by processor 602. For example, the memory 604 may store program code that is executed by the processor 602 to implement particular test insertion functionality of module 610 within an overall integrated circuit design process. The memory 604 is an example of what is more generally referred to herein as a computer-readable medium or other type of computer program product having computer program code embodied therein, and may comprise, for example, electronic memory such as random access memory (RAM) or read-only memory (ROM), magnetic memory, optical memory, or other types of storage devices in any combination. The processor 602 may comprise a microprocessor, CPU, ASIC, FPGA or other type of processing device, as well as portions or combinations of such devices.

As indicated previously, the integrated circuit 102 may be incorporated into a computer, server, communication device or other type of processing device. An example of such a processing device is the processing device 700 shown in FIG. 7. This processing device includes, in addition to integrated circuit 102, processing circuitry 702 and memory 704. The processing circuitry 702 of processing device 700 may comprise a microprocessor, CPU, ASIC, FPGA or other type of processing device, as well as portions or combinations of such devices. The processing circuitry 702 is coupled to the memory 704 and to a network interface 705. The network interface 705 permits the processing device 700 to communicate with other devices and systems over one or more networks, and may therefore comprise, by way of example, one or more conventional transceivers.

The integrated circuit 102 may incorporate and execute software for controlling test functionality of the type described herein. Such software may be stored in a memory of the integrated circuit itself, or in additional memory 704 of associated processing device 700. These and other memories used to store software may each be viewed as an example of what is more generally referred to herein as a computer-readable medium or other type of computer program product having computer program code embodied therein, and may comprise, for example, electronic memory such as RAM or ROM, multi-level memory, magnetic memory, optical memory, or other types of storage devices in any combination.

It is apparent from the above that embodiments of the invention may be implemented in the form of integrated circuits. In a given such integrated circuit implementation, identical die are typically formed in a repeated pattern on a surface of a semiconductor wafer. Each die includes at least first and second test circuitry as described above, and may include other structures or circuits. The individual die are cut or diced from the wafer, then packaged as an integrated circuit. One skilled in the art would know how to dice wafers and package die to produce integrated circuits. Integrated circuits so manufactured are considered embodiments of this invention.

It should again be emphasized that the embodiments of the invention as described herein are intended to be illustrative only. For example, other embodiments of the invention can be implemented using a wide variety of other types of test circuitry, with different types of logic gates, flip-flops or other circuit elements, as well as different types and arrangements of circuit cores, functional logic, and associated control signaling, than those included in the embodiments described herein. Also, the particular assumptions made herein in describing the illustrative embodiments should be considered examples only and need not apply in other embodiments. These and numerous other alternative embodiments within the scope of the following claims will be readily apparent to those skilled in the art.

What is claimed is:

1. An integrated circuit comprising:
a primary input adapted to receive a test control signal;
a primary output;
a plurality of logic circuits having inputs coupled to the primary input via respective fan-out paths of the primary input;
first test circuitry configured for testing a designated portion of the integrated circuit in a first test mode of operation with the test control signal at a first logic value; and
second test circuitry coupled between the inputs of the logic circuits and the primary output and configured for testing of the fan-out paths in a second test mode of operation in which the test control signal takes on both the first logic value and a second logic value associated with a functional mode of operation.

2. The integrated circuit of claim 1 wherein the primary input, primary output and plurality of logic circuits are part of a designated circuit core that further includes additional primary inputs, primary outputs and logic circuits.

3. The integrated circuit of claim 2 wherein the designated circuit core comprises a system-on-chip core of the integrated circuit.

4. The integrated circuit of claim 1 wherein the first test circuitry comprises scan test circuitry of the integrated circuit.

5. The integrated circuit of claim 4 wherein the scan test circuitry comprises a plurality of scan channels associated with respective additional primary outputs of the integrated circuit.

6. The integrated circuit of claim 1 wherein the second test circuitry comprises a plurality of scan cells coupled to respective ones of the inputs of the logic circuits.

7. The integrated circuit of claim 1 wherein the second test circuitry comprises:
a logic gate having inputs coupled to respective ones of the inputs of the logic circuits; and
a flip-flop having one of a reset input and a set input coupled to an output of the logic gate.

8. The integrated circuit of claim 7 wherein the flip-flop has a data input coupled to a voltage potential, a data output coupled to the primary output, and a clock input adapted to receive a reference clock signal.

9. The integrated circuit of claim 7 wherein the logic gate comprises an OR gate and the flip-flop has an active low reset input coupled to an output of the OR gate.

10. The integrated circuit of claim 7 wherein the logic gate comprises an AND gate and the flip-flop has an active low set input coupled to an output of the AND gate.

11. The integrated circuit of claim 1 wherein the second test mode comprises at least first and second phases in which the test control signal is at the respective first and second logic values.

12. The integrated circuit of claim 11 wherein the second test circuitry is configured to permit detection of a stuck-at fault on at least one of the fan-out paths through observation of the primary output in the first and second phases.

13. The integrated circuit of claim 12 wherein the stuck-at fault is detected if a logic value observed at the primary output is different than its expected logic value given the logic value of the test control signal in the corresponding phase of the second test mode.

14. A processing device comprising the integrated circuit of claim 1.

15. A method comprising:
testing a designated portion of an integrated circuit in a first test mode of operation with a test control signal applied to a primary input of the integrated circuit at a first logic value; and
testing fan-out paths between the primary input and inputs of respective logic circuits of the integrated circuit in a second test mode of operation in which the test control signal takes on both the first logic value and a second logic value associated with a functional mode of operation.

16. The method of claim 15 wherein testing fan-out paths comprises:
applying the test control signal at the first logic value in a first phase of the second test mode;
observing the primary output in the first phase;
applying the test control signal at the second logic value in a second phase of the second test mode;
observing the primary output in the second phase; and
detecting a stuck-at fault on at least one of the fan-out paths based on the observations of the primary output in the first and second phases.

17. The method of claim 16 wherein detecting a stuck-at fault further comprises:
detecting the stuck-at fault if a logic value observed at the primary output is different than its expected logic value given the logic value of the test control signal in the corresponding phase of the second test mode.

18. The method of claim 17 wherein detecting a stuck-at fault further comprises:
identifying a stuck-at-1 fault on at least one of the fan-out paths if the test control signal is at a logic 0 value and the primary output is at a logic value different than that expected given that the test control signal is at the logic 0 value; and
identifying a stuck-at-0 fault on at least one of the fan-out paths if the test control signal is at a logic 1 value and the primary output is at a logic value different than that expected given that the test control signal is at the logic 1 value.

19. A computer program product comprising a non-transitory computer-readable storage medium having computer program code embodied therein, wherein the computer program code when executed causes the integrated circuit to perform the method of claim 15.

20. A processing system comprising:
a processor; and
a memory coupled to the processor and configured to store information characterizing a design of an integrated circuit;
wherein the processing system is configured to provide, within the integrated circuit design:
first test circuitry configured for testing a designated portion of the integrated circuit in a first test mode of operation with a test control signal applied to a primary input of the integrated circuit at a first logic value; and
second test circuitry configured for testing fan-out paths between the primary input and inputs of respective logic circuits of the integrated circuit in a second test mode of operation in which the test control signal takes on both the first logic value and a second logic value associated with a functional mode of operation.
